(19) United States
(12) Patent Application Publication
(10) Pub. No.: US 2026/0255536 A1
(43) Pub. Date: Aug. 27, 2026

(54) EFFICIENT WATER-COOLING RADIATOR THAT IS EASY TO DISASSEMBLE AND ASSEMBLE

(71) Applicant: JIETE TECHNOLOGY CO.,LTD, Qingyuan (CN)

(72) Inventor: ANDING FANG, Qingyuan (CN)

(21) Appl. No.: 19/081,088

(22) Filed: Mar. 17, 2025

(30) Foreign Application Priority Data
Feb. 24, 2025 (CN) 202520300112.2

(51) Int. Cl. H05K 7/20

(52) U.S. Cl. CPC H05K 7/20272

(57) ABSTRACT

The present invention discloses an efficient water-cooling radiator that is easy to disassemble and assemble, comprising a water pump component and a cooling component; the cooling component is installed on a limit component for dissipating heat from internal components of the computer, and the water pump component is installed on the limit component for providing fluid power for easy disassembly of the radiator. The water pump component and cooling component have a buckle disassembly structure, the water pump component is rotatably snap-fitted to the cooling component, facilitating the disassembly of the radiator for component cleaning, maintenance, replacement, and upgrading; the water-cooling radiator also includes a locking screw disassembly structure which locks the water pump component vertically onto the cooling component through screws.

### CROSS-REFERENCE TO RELATED APPLICATIONS

This application claims priority to Chinese Patent Application No. 202520300112.2, filed on February 24, 2025, which is hereby incorporated by reference in its entirety.

### TECHNICAL FIELD

The present invention relates to the technical field of heat dissipation devices, specifically an efficient water-cooling radiator that is easy to disassemble and assemble.

### BACKGROUND

The rapid development of computer technology has continuously pushed the improvement of computing power of high-performance processors and graphics processing units (GPUs), and higher power consumption and heat generation. In order to effectively manage the temperature of these high heat components, ensure stable operation of computer systems, and extend hardware lifespan, water-cooling radiating technology has gradually become the preferred cooling solution for high-performance computing platforms and gaming computers. Water-cooling radiators absorb and remove heat from heating components such as CPUs and GPUs through circulating water or specialized coolant, and then dissipate the heat into the air through the heat dissipation fins and fans on the radiator. Compared to traditional air cooling, water-cooling radiators have higher heat dissipation efficiency and lower noise level.

Existing water-cooling radiators, however, often suffer from complex and time-consuming installation and disassembly processes. Many water-cooling radiators, for example, require users to have high manual dexterity, involving complex pipeline connections, screw fixation, and coolant filling steps, which may pose certain challenges for ordinary users and increase the risk of errors during installation, such as leakage and decreased heat dissipation performance caused by improper installation. In addition, existing water-cooling radiators often require disassembly of the entire machine or part of the hardware for maintenance or component replacement, which not only increases maintenance costs but may also affect the stability and service life of other hardware. To solve this problem, the inventor proposes an efficient water-cooling radiator that is easy to disassemble and assemble.

### SUMMARY

In response to the shortcomings of the above-mentioned technologies, the present invention provides an efficient water-cooling radiator that is easy to disassemble and assemble.

In order to achieve the above purpose, the present invention adopts the following technical solution: an efficient water-cooling radiator that is easy to disassemble and assemble, comprising a limit component, a cooling component, a detachable component, a water pump component, a buckle disassembly mechanism, and a partition plate; wherein the cooling component is installed on the limit component for dissipating heat from internal components of the computer, the detachable component is installed on the limit component for easy disassembly of the heat sink, the partition plate is installed inside the detachable component, the water pump component is installed on the top of the detachable component, the buckle disassembly mechanism is located between the detachable component and the limit component, comprising a first rotary card and a second rotary card, the detachable component comprises a detachable plate disposed on the limit component to facilitate the disassembly of a heat sink, and the detachable plate internally has a plurality of limit holes spaced apart, and also has a locking screw that is vertically installed on the limit component and runs through the limit hole for limiting the detachable plate, the detachable plate extends outward and is provided with a first rotating card installed at one end of the detachable plate, and the partition plate is disposed inside the detachable plate.

As a further elaboration, the limit component comprises a base and a limit column, and the limit column is vertically installed on the base and a plurality of limit columns are spaced apart.

As a further elaboration, the efficient water-cooling radiator that is easy to disassemble and assemble further comprises a limit plate and a fixing rod, the limit plate is installed inside the cooling component, the fixing rod is vertically installed inside the limit plate for further limiting the detachable plate, and the detachable plate is disposed at the top of the limit plate.

As a further elaboration, the water pump assembly comprises a water pump vertically installed on the detachable plate, and an impeller installed on one end of the water pump.

As a further elaboration, the cooling component comprises a water-cooling chamber installed on the base, wherein the limit plate is located inside the water-cooling chamber, and the second rotary card is installed on a side wall of the water-cooling chamber, a plurality of second rotary cards are spaced apart, and the second rotary card mutually fits with the first rotary card.

As a further elaboration, the water-cooling chamber extends outward and is provided with a connecting pipe, and the connecting pipe is installed at one end of the water-cooling chamber.

As a further elaboration, the connecting pipe extends outward and is provided with an inlet water nozzle installed at one end of the connecting pipe, the connecting pipe extends outward and is provided with an outlet water nozzle, and the outlet water nozzle is installed at one end of the connecting pipe and away from the inlet water nozzle.

As a further elaboration, the efficient water-cooling radiator that is easy to disassemble and assemble further comprises a heat dissipation copper bottom installed at one end of the base for dissipating heat from the equipment.

In summary, the present invention has the following beneficial effects: an efficient water-cooling radiator that is easy to disassemble and assemble is designed with a detachable component, a detachable plate, and a limit hole on the detachable plate that fits with a locking screw, users can easily disassemble and assemble the radiator, thereby facilitating cleaning, maintenance, or component replacement, improving the maintainability and service life of the radiator. The second rotary card on the water-cooling chamber fits with the first rotary card on the detachable plate, providing an innovative fixing method that not only enhances the stability of the radiator, but also makes the disassembly process more convenient.

### BRIEF DESCRIPTION OF DRAWINGS

FIG. 1 is a schematic diagram of the three-dimensional structure of an efficient water-cooling radiator that is easy to disassemble and assemble according to the present invention;

FIG. 2 is a front view of an efficient water-cooling radiator that is easy to disassemble and assemble according to the present invention;

FIG. 3 is a schematic diagram of the internal structure of an efficient water-cooling radiator that is easy to disassemble and assemble according to the present invention;

FIG. 4 is an exploded schematic diagram of an efficient water-cooling radiator that is easy to disassemble and assemble according to the present invention;

FIG. 5 is an exploded schematic diagram of an efficient water-cooling radiator that is easy to disassemble and assemble according to the present invention.

### DESCRIPTION OF EMBODIMENTS

The technical solutions in the embodiments of the present invention will be described clearly and completely in conjunction with the accompanying drawings of the embodiments of the present invention. Obviously, the described embodiments are only a part of the embodiments of the present invention, rather than all the embodiments. Based on the embodiments of the present invention, all other embodiments obtained by those of ordinary skill in the art without creative work shall fall within the protection scope of the present invention.

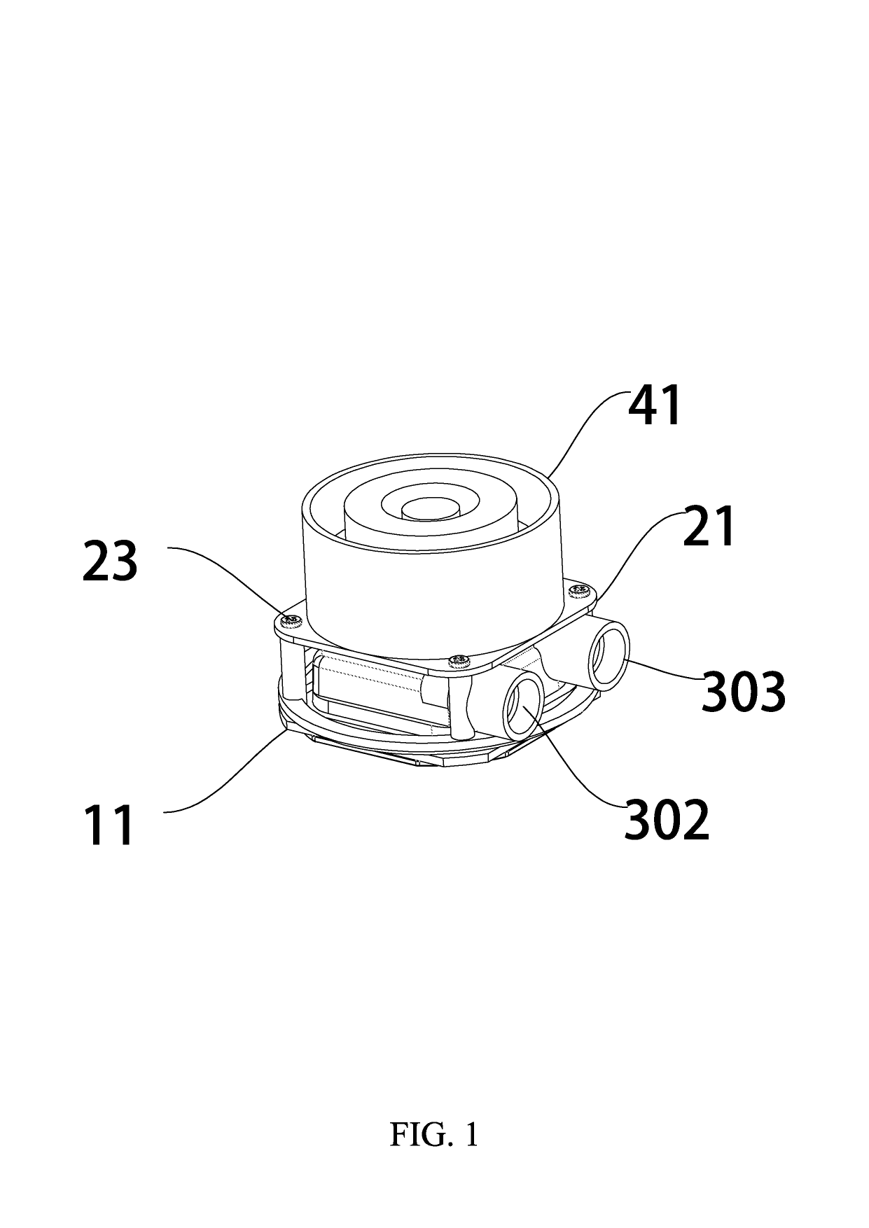

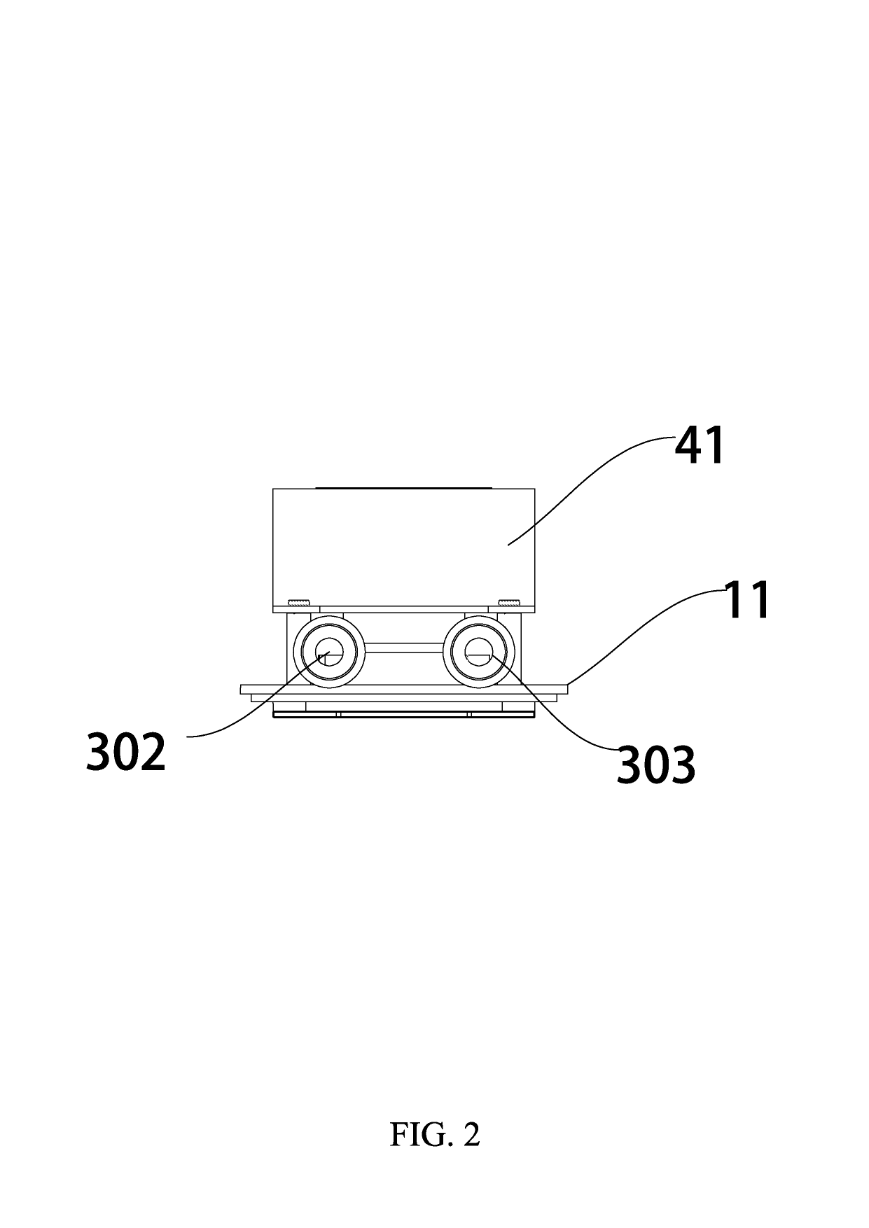

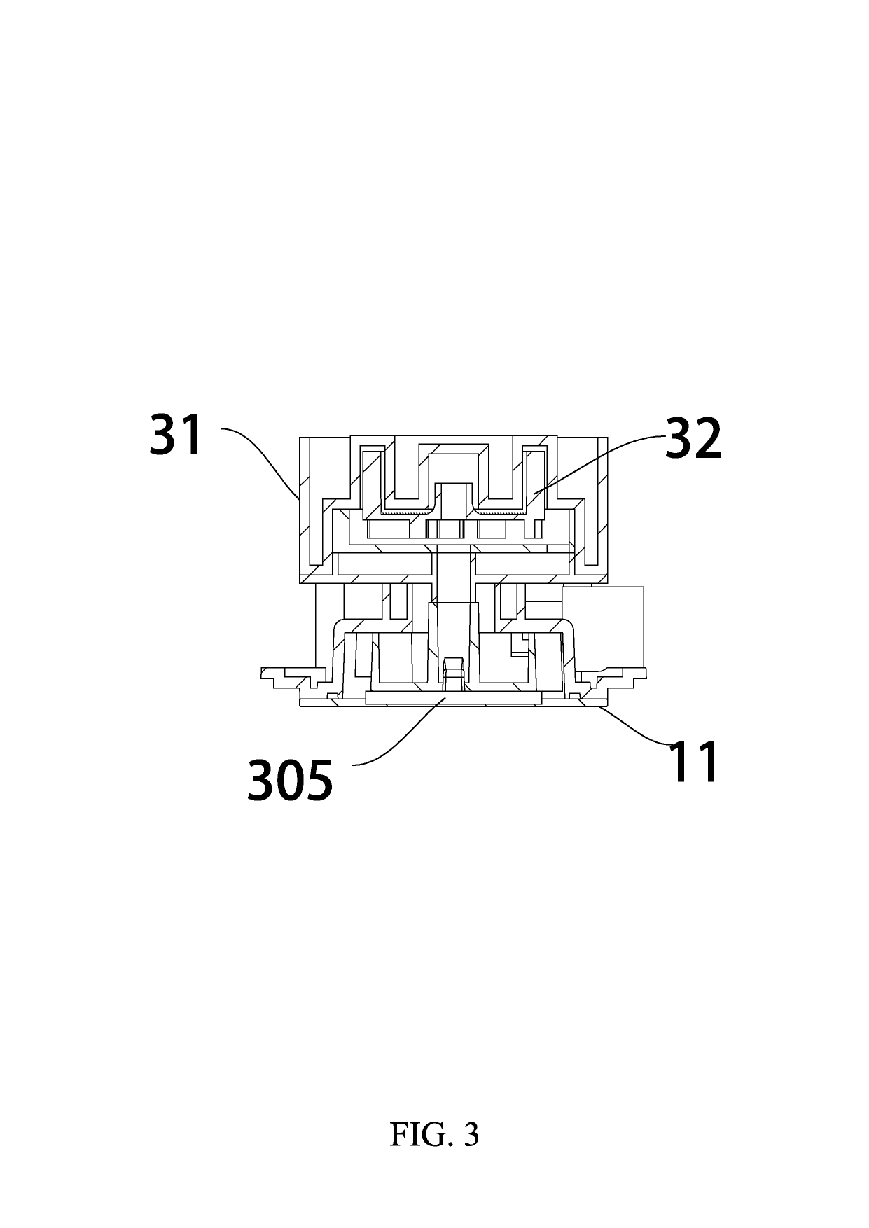

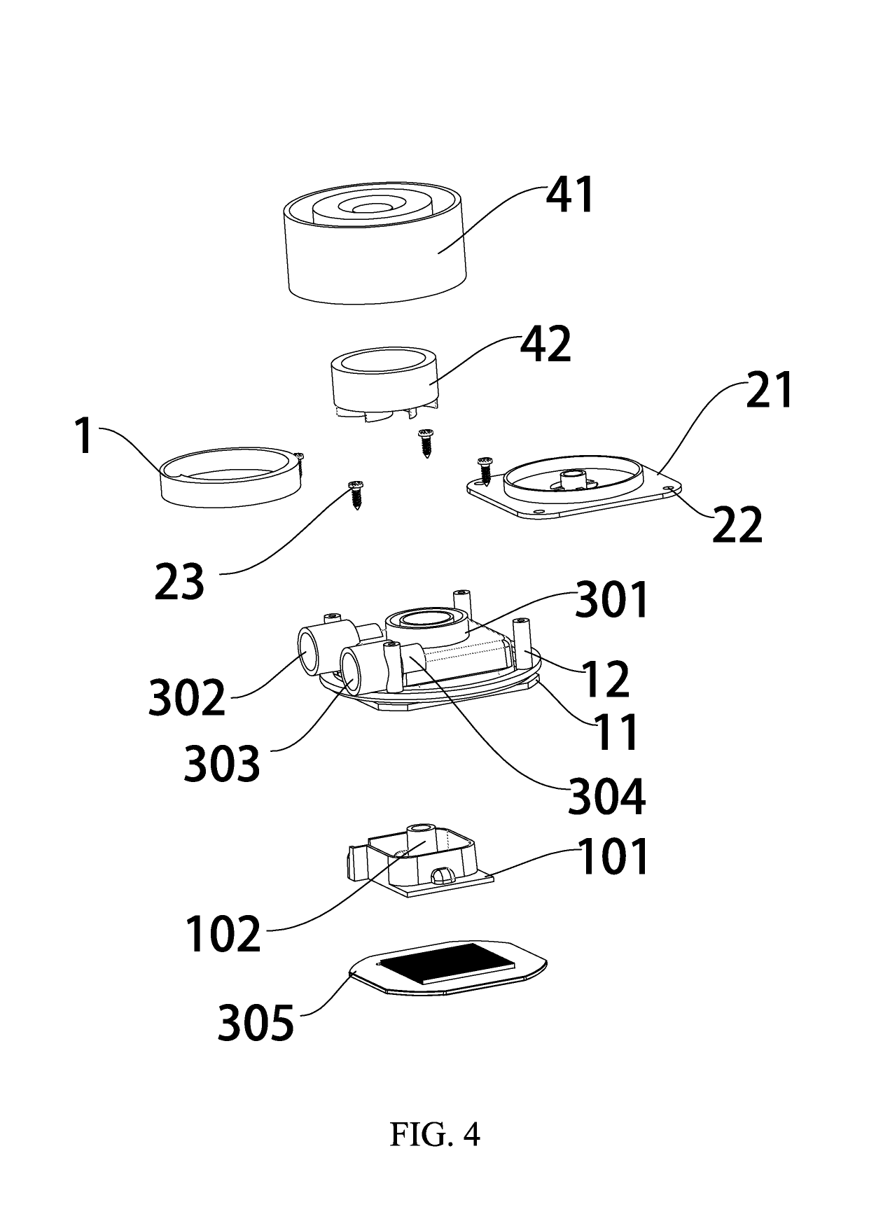

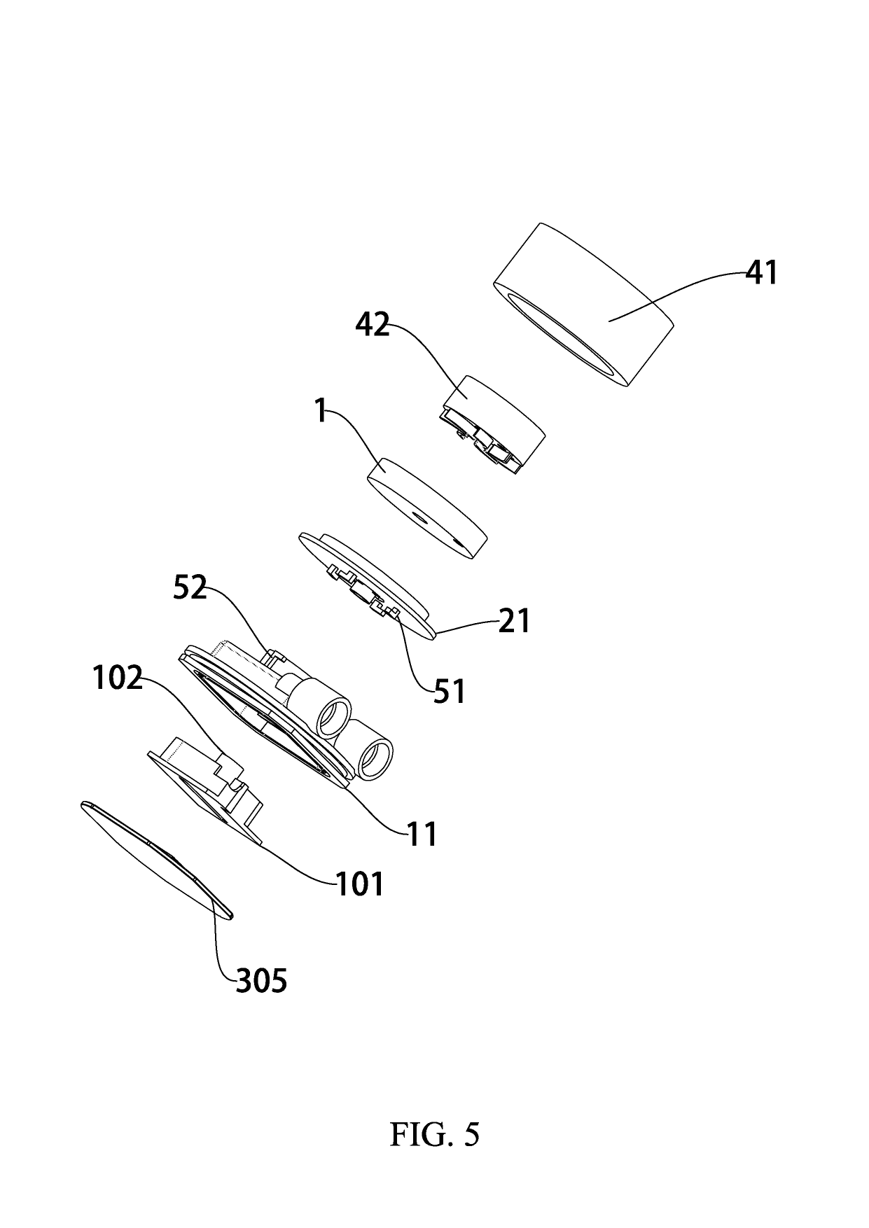

As shown in FIG. 1-5, the present invention provides an efficient water-cooling radiator that is easy to disassemble and assemble, comprising a limit component, a cooling component, a detachable component, a water pump component, a buckle disassembly mechanism, and a partition plate 1; wherein the cooling component is installed on the limit component for dissipating heat from internal components of the computer, the detachable component is installed on the limit component for easy disassembly of the heat sink, the partition plate 1 is installed inside the detachable component, the water pump component is installed on the top of the detachable component, the buckle disassembly mechanism is located between the detachable component and the limit component, comprising a first rotary card 51 and a second rotary card 52, the detachable component comprises a detachable plate 21 disposed on the limit component to facilitate the disassembly of a heat sink, and the detachable plate 21 internally has a plurality of limit holes 22 spaced apart, and also has a locking screw 23 that is vertically installed on the limit component and runs through the limit hole 22 for limiting the detachable plate 21, the detachable plate 21 extends outward and is provided with a first rotating card installed at one end of the detachable plate 21, and the partition plate 1 is disposed inside the detachable plate 21.

Specifically, the locking screw 23 runs through the limit hole 22 on the detachable plate 21, firmly fixing the detachable plate 21 to the limit column 12, thereby achieving the convenient disassembly and assembly function of the radiator. By loosening the locking screw 23, users can easily remove the detachable plate 21 and its internal partition plate 1, cooling component, and other components from the limit component for cleaning, maintenance, or replacement operations.

The limit component comprises a base 11 and a limit column 12, and the limit column 12 is vertically installed on the base 1 and a plurality of limit columns 12 are spaced apart, and the locking screw 23 is disposed inside the limit column 12.

Specifically, the designed base 11 and limit column 12 not only ensures the stability of heat sink, but also provides an installation position for locking screw 23.

The efficient water-cooling radiator that is easy to disassemble and assemble also includes a limit plate 101 and a fixing rod 102, the limit plate 101 is installed inside the cooling component, the fixing rod 102 is vertically installed inside the limit plate for further limiting the detachable plate 21, and the detachable plate 21 is disposed at the top of the limit plate 101.

Specifically, in order to further enhance the stability and heat dissipation effect of the radiator, the limit plate 101 and the fixing rod 102 are designed to further limit and support the detachable plate 21. The limit plate 101 is installed inside the cooling component, while the fixing rod 102 is vertically installed inside the limit plate 101, and they work together on the top of the detachable plate 21 to ensure the stability and efficiency of the heat sink during the heat dissipation process.

The water pump assembly comprises a water pump 41 vertically installed on the detachable plate 21, and an impeller 42 installed on one end of the water pump 41.

Specifically, the water pump of the cooling component is activated to drive the impeller to rotate, thereby sucking in and pushing the coolant (such as water or specialized coolant) to circulate inside the radiator.

The cooling component comprises a water-cooling chamber 301 installed on the base 11, and the limit plate 101 is located inside the water-cooling chamber 301, and the second rotary card 52 is installed on a side wall of the water-cooling chamber 301, a plurality of second rotary cards 52 are spaced apart, and the second rotary card 52 mutually fits with the first rotary card 51; the water-cooling chamber 301 extends outward and is provided with a connecting pipe 304, and the connecting pipe 304 is installed at one end of the water-cooling chamber 301, the connecting pipe 301 extends outward and is provided with an inlet water nozzle 303 installed at one end of the connecting pipe 304, the connecting pipe 304 extends outward and is provided with an outlet water nozzle 302, and the outlet water nozzle 302 is installed at one end of the connecting pipe 304 and away from the inlet water nozzle 304.

The cooling component also comprises a heat dissipation copper base 305, which is installed at one end of the base 11 for dissipating heat from the device.

Specifically, the coolant passes through the water-cooling chamber 301 installed on the base 11 and exchanges heat with internal computer components that require heat dissipation, such as the CPU or GPU that are in close contact with the copper bottom 305. After absorbing the heat released by these components, the coolant experiences temperature rise, and in order to dissipate the absorbed heat, the coolant is then guided to the outside of the radiator through connecting pipe 304. One end of the connecting pipe 304 is provided with a water inlet 303 for injecting new coolant into the radiator, while the other end is provided with a water outlet 302 for discharging the heated coolant. By continuously circulating and replacing with new coolant, the radiator can effectively remove the heat inside the computer.

In addition, the second rotary card on the water-cooling chamber 301 fits with the first rotary card on the detachable plate, providing a convenient way of fixing and disassembling that further simplifies the operation process.

For those skilled in the art, obviously, the present invention is not limited to the details of the exemplary embodiments described above, and can be implemented in other specific forms without departing from the spirit or essential features of the present invention. Therefore, from any point of view, the embodiments shall be regarded as exemplary and non limiting, and the scope of the present invention is limited by the appended claims rather than the above description. Therefore, it is intended to encompass all variations falling within the meaning and scope of the equivalent elements of the claims within the scope hereof. Any reference numerals in the claims shall not be regarded as limiting the claims involved.

In addition, it should be understood that although this specification is described according to the embodiments, not each embodiment only contains an independent technical solution, and the description in the specification is only for clarity, and those skilled in the art should consider the specification as a whole, and the technical solutions in each embodiment can also be appropriately combined to form other embodiments that those skilled in the art can understand.

What is claimed is:

1. An efficient water-cooling radiator that is easy to disassemble and assemble, comprising a limit component;
a cooling component, installed on the limit component for dissipating heat from internal components of the computer;
a detachable component, installed on the limit component for easy disassembly of the heat sink;
a partition plate, installed inside the detachable component;
a water pump component, installed on the top of the detachable component;
a buckle disassembly mechanism, located between the detachable component and the limit component, comprising a first rotary card and a second rotary card;
the detachable component comprises a detachable plate disposed on the limit component to facilitate the disassembly of a heat sink, wherein the detachable plate internally has a plurality of limit holes spaced apart, extends outward and is provided with a first rotating card installed at one end of the detachable plate, and the partition plate is disposed inside the detachable plate;
the limit component comprises a base and a limit column, and the limit column is vertically installed on the base and a plurality of limit columns are spaced apart.

2. The efficient water-cooling radiator that is easy to disassemble and assemble according to claim 1, further comprising a limit plate and a fixing rod, the limit plate is installed inside the cooling component, the fixing rod is vertically installed inside the limit plate for further limiting the detachable plate, and the detachable plate is disposed at the top of the limit plate.

3. The efficient water-cooling radiator that is easy to disassemble and assemble according to claim 2, wherein the detachable component comprises a locking screw that is vertically installed on the limit column and runs through the limit hole for limiting the detachable plate.

4. The efficient water-cooling radiator that is easy to disassemble and assemble according to claim 3, wherein the water pump assembly comprises a water pump vertically installed on the detachable plate, and an impeller installed on one end of the water pump.

5. The efficient water-cooling radiator that is easy to disassemble and assemble according to claim 4, further comprising a water-cooling chamber installed on the base, wherein the limit plate is located inside the water-cooling chamber, and the second rotary card is installed on a side wall of the water-cooling chamber, a plurality of second rotary cards are spaced apart, and the second rotary card mutually fits with the first rotary card.

6. The efficient water-cooling radiator that is easy to disassemble and assemble according to claim 5, wherein the water-cooling chamber extends outward and is provided with a connecting pipe, and the connecting pipe is installed at one end of the water-cooling chamber.

7. The efficient water-cooling radiator that is easy to disassemble and assemble according to claim 6, wherein the connecting pipe extends outward and is provided with an inlet water nozzle installed at one end of the connecting pipe, the connecting pipe extends outward and is provided with an outlet water nozzle, and the outlet water nozzle is installed at one end of the connecting pipe and away from the inlet water nozzle.

8. The efficient water-cooling radiator that is easy to disassemble and assemble according to claim 7, further comprising a heat dissipation copper bottom installed at one end of the base for dissipating heat from the equipment.
